(19) United States
(12) Patent Application Publication
(10) Pub. No.: US 2012/0002092 A1
(43) Pub. Date: Jan. 5, 2012

(54) LOW NOISE ACTIVE PIXEL SENSOR

(76) Inventor: Robert M. Guidash, Rochester, NY (US)

(21) Appl. No.: 12/826,725

(22) Filed: Jun. 30, 2010

(51) Int. Cl. H04N 5/335; H01L 27/146

(52) U.S. Cl. 348/308; 250/208.1

(57) ABSTRACT

A vertically-integrated active pixel sensor includes a sensor layer connected to a circuit layer. At least one pixel region on the sensor layer includes a photodetector and a charge-to-voltage converter. At least one pixel region on the circuit layer consists of a source follower input transistor. A connector connects the charge-to-voltage converter to a gate of the source follower input transistor. The connector is used to transfer a signal from the charge-to-voltage converter to the source follower input transistor.

### TECHNICAL FIELD

The invention relates generally to the field of active pixel sensors, and more particularly to active pixel sensors having two separate semiconductor layers with each layer including a portion of the electrical circuitry.

### BACKGROUND

Pixel sizes in CMOS Image Sensors (CIS) and Active Pixel Sensors (APS) continue to decrease in order to obtain higher and higher image resolutions. To maintain a reasonable fill factor in the smaller pixels, the sizes of the Field Effect Transistors (FET) within the pixels must also shrink. Smaller sized pixel FETs, especially for the source follower input transistor, result in a substantial increase in Random Telegraph Signal (RTS) noise of those FETs. This increase in RTS noise can significantly degrade the low light Signal to Noise Ratio (SNR) of the image sensor. Degradation of low light SNR is described in an article by P. Martin-Gonthier et al., entitled “Low-Frequency Noise Impact on CMOS Image Sensors”, 24th Conference on Design of Circuits and Integrated Systems (DCIS '09, 18-20 Nov. 2009, Zaragoza, Spain).

Larger sized FETs in the pixel array readout path can mitigate the increased RTS noise. One way to provide larger FETs in the readout path is to build the photodetector separately from the pixel FETs. The image sensor, for example, can be built on separate wafers, and the wafers joined together using three-dimensional integration or wafer-level interconnect technologies. U.S. Pat. No. 6,927,432 fabricates an active pixel sensor using two semiconductor wafers. One wafer, the donor wafer, includes the photodetectors while another wafer, the host wafer, includes an interconnect layer and electrical circuits for in-pixel signal operations and read out of the photodetectors. Pixel interconnects directly connect each photodetector on the donor wafer to a respective node or circuit on the host wafer.

Although this approach separates the processing of the photodetector and pixel FETs, it degrades photodetector performance due to the direct contact or connection with the photodetector. Specific examples of such performance degradation include, but are not limited to, increased dark current due to damage from the contact etch process, increased metallic contamination in the photodetector leading to point defects, and high dark current due to being connected to a highly doped ohmic contact region. In addition, three pixel FETs are included in each pixel on the host wafer, so for small pixel CIS or APS devices (i.e. pixel sizes less than 1.4 micrometers (um)), the size of each pixel FET is still such that increased RTS noise is incurred.

In United States Patent Application Publication 2008/0083939, a three-dimensional integration pixel architecture is disclosed where components of the CIS or APS pixel are distributed or partitioned on multiple wafers that are electrically interconnected. An embodiment that uses two wafers is described where the two wafers are referred to as the sensor wafer and the circuit wafer. While this pixel architecture solves the problem of degraded photodetector performance, a pixel can include three pixel FETs on the circuit wafer. As a result, the FETs are typically smaller than 1 μm² and can have increased RTS noise.

In United States Patent Application Publication 2009/0242950, a three-dimensional integration pixel architecture is disclosed where components of the CIS or APS pixel are distributed or partitioned on multiple wafers that are electrically interconnected. In this design, the reset FET is retained in the pixel on the sensor wafer. As a result, a pixel can include two pixel FETs on the circuit wafer. While the pixel FET size can be increased somewhat in this architecture, for pixel sizes less than 1.4 um, the size of each pixel FET can still result in increased RTS noise.

### SUMMARY

An image sensor has at least two semiconductor layers with a sensor layer including a first plurality of pixel regions. The term “sensor layer” includes a sensor wafer and a sensor die. At least one of the pixel regions includes a photodetector for collecting charge in response to incident light, a charge-to-voltage converter, and a transfer gate for enabling charge transfer from the photodetector to the charge-to-voltage converter. The at least one pixel region can also include a reset transistor for discharging charge from the charge-to-voltage converter or alternatively, two or more pixel regions on the sensor layer can share a reset transistor. The charge-to-voltage converter can be shared by two or more pixel regions on the sensor layer.

A circuit layer is connected to the sensor layer. The term “circuit layer” includes a circuit wafer and a circuit die. The circuit layer includes a second plurality of pixel regions with at least one pixel region consisting of a source follower input transistor. A size of the source follower input transistor can fill or substantially fill an area of the pixel region on the circuit layer. A connector directly connects each charge-to-voltage converter on the sensor layer to a gate of a respective source follower input transistor on the circuit layer. The connector is used to transfer a signal from each charge-to-voltage converter to respective source follower input transistors. The pixel regions on the circuit layer can be directly connected to single respective pixel regions on the sensor layer. The pixel region on the circuit layer can be shared by two or more pixel regions on the sensor layer. The image sensor can be included in an image capture device.

A first row select signal line is included in the at least one pixel region on the sensor layer and a second row select signal line is included in the at least one pixel region on the circuit layer. The first and second row select lines can be connected together and to a common signal in an embodiment in accordance with the invention. Alternatively, in another embodiment, the first and second row select signal lines can be unconnected and controlled by separate signals.

### ADVANTAGEOUS EFFECT

The present invention includes the advantages of having both high image quality with low RTS noise and high fill factor for large and small pixels. The entire area of a pixel region on the circuit layer can be dedicated to a single transistor, typically a source follower input transistor. As a result, the source follower input transistor can be made large enough to provide low RTS noise. In addition, the fabrication process for the sensor layer can be optimized for photodetector performance while the fabrication process for the circuit layer can be optimized for CMOS processing and circuit performance. The sensor layer can be used with multiple circuit layer designs or technologies, thereby providing improved design flexibility and optimization along with reduced costs. The connection between the sensor layer and the circuit layer can be achieved through the charge-to-voltage converter on the sensor layer, a voltage domain contact, and a node on the circuit layer, thereby avoiding performance degradation of the photodetectors. The connection between the sensor layer and the circuit layer can be achieved through a direct connection between each charge-to-voltage converter on the sensor layer and a respective gate of a source follower input transistor on the circuit layer, thereby reducing charge-to-voltage converter capacitance and bright point defects. Bright point defects from the circuit layer are eliminated because only the gate of the source follower input transistor is connected to the charge-to-voltage converter. The charge-to-voltage converter is not connected to a source/drain region on the circuit layer. Those skilled in the art will recognize that dislocations and other defects in source/drain regions are more difficult to control and eliminate as transistor size is scaled to smaller dimensions. Therefore, making a direct connection to a gate on the circuit layer eliminates bright point defects from the source/drain connection on the circuit layer for current designs. This allows designers to use existing transistors on the circuit layer without modification of the source/drain regions.

### BRIEF DESCRIPTION OF THE DRAWINGS

Embodiments of the invention are better understood with reference to the following drawings. The elements of the drawings are not necessarily to scale relative to each other.

FIG. 1a is a top view of two semiconductor wafers with multiple image sensors formed therein in an embodiment in accordance with the invention;

FIG. 1b is a top view of an image sensor suitable for use as an image sensor 101 shown in FIG. 1a in an embodiment in accordance with the invention;

FIG. 1c is a top view of a pixel array suitable for use as pixel array 100 shown in FIGS. 1a and 1b in an embodiment in accordance with the invention;

FIG. 2 is a schematic diagram of a pixel region suitable for use in pixel region 106 shown in FIG. 1c in an embodiment in accordance with the invention;

FIG. 3 is a schematic diagram of a shared architecture of pixel regions in an embodiment in accordance with the invention;

FIG. 4 is a cross-sectional view along line A-A′ in FIG. 1c of two pixel regions having the pixel schematic as shown in FIG. 2 in an embodiment in accordance with the invention; and

FIG. 5 is a block diagram of an imaging system suitable for employing an image sensor as depicted in FIG. 1 in an embodiment in accordance with the invention.

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected, or an indirect connection through one or more passive or active intermediary devices. The term “circuit” means either a single component or a multiplicity of components, either active or passive, that are connected together to provide a desired function. The term “signal” means at least one current, voltage, charge, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer, sensor die, or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “die” are to be understood as a semiconductor-based material including, but not limited to, silicon, silicon-on-insulator (SOI) technology, silicon-on-sapphire (SOS) technology, doped and undoped semiconductors, epitaxial layers or well regions formed on a semiconductor substrate, and other semiconductor structures.

Referring to the drawings, like numbers indicate like parts throughout the views.

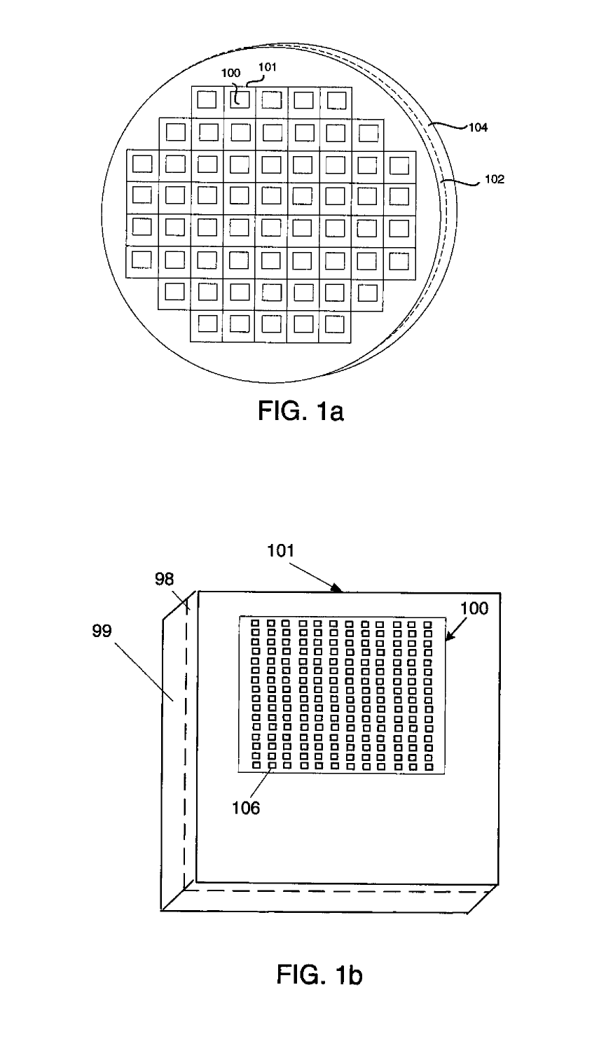

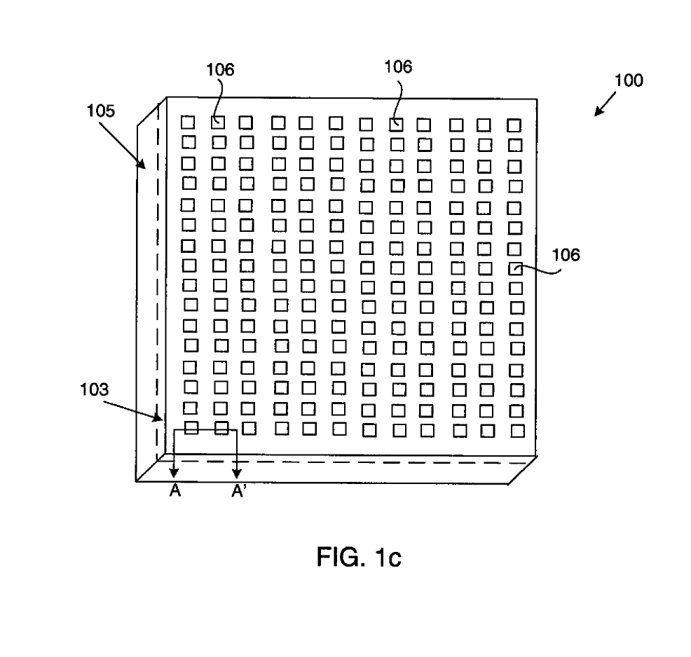

FIG. 1a is a top view of two semiconductor wafers with multiple image sensors formed therein in an embodiment in accordance with the invention. The two semiconductor wafers will be herein referred to as a sensor wafer 102 and a circuit wafer 104. Semiconductor sensor wafer 102 contains multiple image sensors 101, each with a pixel array 100 in an embodiment in accordance with the invention. The image sensors 101 on the sensor wafer 102 can be electrically connected to a corresponding circuit die 99 (see FIG. 1b) on a circuit wafer 104 by bonding the sensor wafer 102 and circuit wafer 104 together using a process known in the art. Alternatively, image sensor 101 can have two die in another embodiment in accordance with the invention, where the two die are not connected together at the wafer level. For example, image sensor 101 in FIG. 1b can be constructed by connecting each individual image sensor die 98 to individual circuit die 99. It should also be noted that one or more embodiments in accordance with the invention can connect individual image sensor die 98 to tested and known operable circuit die 99 that are still in wafer form as a circuit wafer 104.

As used herein, the term “sensor layer” is to be understood to mean a sensor wafer and a sensor die, and the term “circuit layer” is to be understood to mean a circuit wafer and a circuit die.

The preferred embodiment utilizes wafer level bonding and interconnection of a sensor wafer 102 to a circuit wafer 104. Referring to FIG. 1a, pixel array 100 is implemented as an active pixel sensor, such as, for example, a pixel array found in a Complementary Metal Oxide Semiconductor (CMOS) image sensor. An active pixel sensor has pixels that each includes one or more active electrical components, such as transistors, within a pixel.

FIG. 1c is a top view of a pixel array suitable for use as pixel array 100 shown in FIGS. 1a and 1b in an embodiment in accordance with the invention. Pixel array 100 includes pixel regions 106 preferably arranged in rows and columns on sensor layer 103. Different arrangements of pixel regions can be implemented in other embodiments in accordance with the invention. Pixel array 100 can have any number of pixels, such as, for example, 1280 columns by 960 rows of pixels.

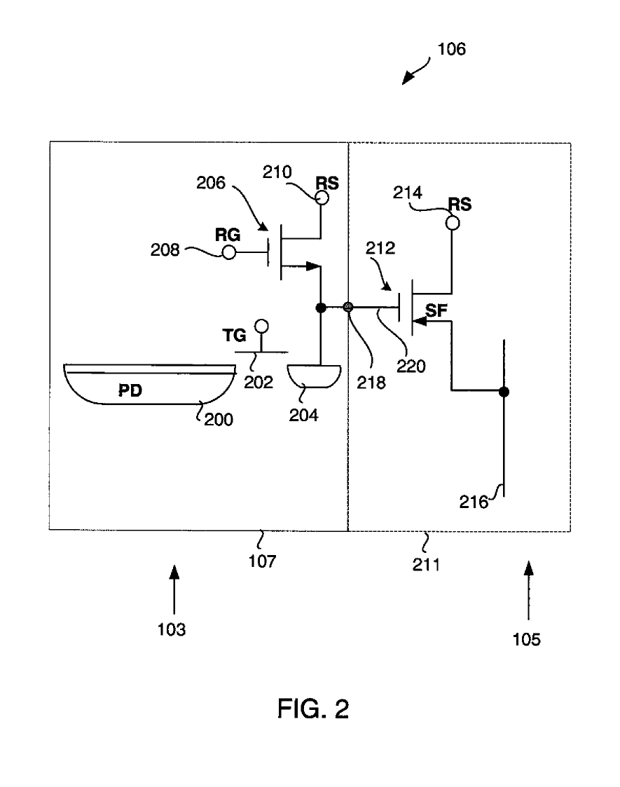

FIG. 2 is a schematic diagram of a pixel region suitable for use in pixel region 106 shown in FIG. 1c in an embodiment in accordance with the invention. Sensor layer pixel region 107 disposed on sensor layer 103 includes photodetector (PD) 200, transfer gate (TG) 202, charge-to-voltage converter 204, and reset transistor 206 having a reset gate (RG) 208. Photodetector 200 collects charge in response to light striking pixel array 100. Transfer gate 202, when activated, enables charge to transfer from photodetector 200 to charge-to-voltage converter 204. Charge-to-voltage converter 204 converts the charge into a representative voltage and is implemented as a floating diffusion in an embodiment in accordance with the invention. Charge-to-voltage converter 204 can be implemented differently in other embodiments in accordance with the invention. For example, charge-to-voltage converter 204 can be implemented as a floating gate region.

Reset transistor 206 is used to discharge charge from the charge-to-voltage converter during a reset operation. The drain of reset transistor 206 is connected to a row select (RS) signal line 210 that is used to perform row select operation on sensor layer pixel region 107. Techniques for performing a row select operation are well known in the art and will not be described in detail herein. By way of example only, one known method for performing a row select operation is known as switched supply row select (SSRS). U.S. Pat. No. 6,323,376 discloses a switched supply row select.

In the illustrated embodiment, sensor layer 103 is implemented as a back side illuminated (BSI) semiconductor wafer. Other embodiments, however, are not limited to a BSI wafer. A front side illuminated (FSI) semiconductor wafer can be used in other embodiments in accordance with the invention. Published United States Patent Application 2008/0083939 disclosed a FSI structure.

Circuit layer pixel region 211 formed on circuit layer 105 includes a source follower input transistor (SF) 212. The drain of source follower input transistor 212 is connected to a row select (RS) signal line 214. RS signal line 214 is used to perform row select operation of circuit layer pixel region 211. The source of source follower input transistor 212 is connected to column output line 216.

Since source follower input transistor 212 is formed on a separate semiconductor wafer than reset transistor 206, the type and structure of the source follower input transistor can be chosen to independently optimize the performance of the source follower input transistor. Because the only active electrical component in pixel region 211 is source follower input transistor 212, the size of source follower input transistor 212 can be made as large, or nearly as large, as the area or size of circuit layer pixel region 211. The size of source follower input transistor 212 can fill or substantially fill circuit layer pixel region 211 in an embodiment in accordance with the invention. For example, if the size of pixel region 106 on sensor layer 103 is 1.4 um, then the product of the length and width of the source follower input transistor 212 can be made close to 1 um². A source follower input transistor at this size has very low RTS noise.

Source follower input transistor 212 is configured as a p-channel Metal Oxide Semiconductor (pMOS) transistor in the illustrated embodiment. pMOS transistors typically have lower noise characteristics than nMOS transistors. Source follower input transistor 212 can be implemented as an n-channel MOS (nMOS) transistor in other embodiments in accordance with the invention.

An pixel region interconnect node 218 connects charge-to-voltage converter 204 on sensor layer 103 to a gate 220 of source follower input transistor 212 on circuit layer 105. In the illustrated embodiment, source follower input transistor 212 is formed in a corresponding pixel region on circuit layer 105, such that there is a one-to-one relationship between the pixel regions on sensor layer 103 and the pixel regions on circuit layer 105.

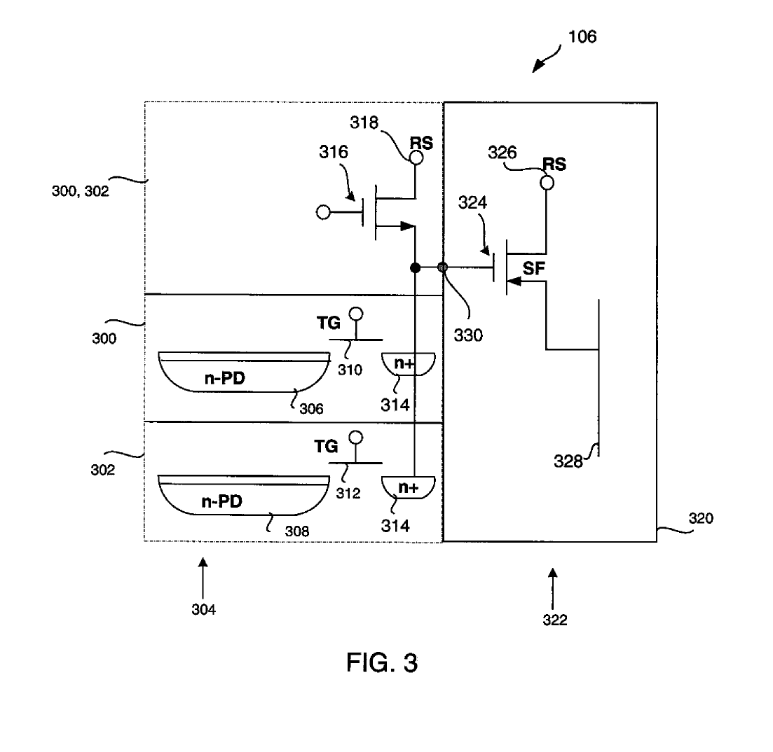

Other embodiments in accordance with the invention can utilize one or more different shared architectures. For example, two or more sensor layer pixel regions 107 on a sensor layer 103 can share circuitry of sensor layer pixel regions 107 on the sensor layer 103. Two or more pixel regions 107 on a sensor layer 103 can share circuitry of circuit layer pixel regions 211 on circuit layer 105. A specific example of such an alternate embodiment is shown in FIG. 3.

Row select signal line 210 and row select signal line 214 can be connected together and to a common signal in an embodiment in accordance with the invention. Alternatively, in another embodiment, row select signal line 210 and row select signal line 214 can be unconnected and controlled by separate signals. It can be advantageous to have row select signal line 210 and row select signal line 214 physically separate with separate control signals since sensor layer 103 and circuit layer 105 can include devices that operate at different supply voltages. Physically separating row select signal line 210 and row select signal line 214 provides design flexibility and the ability to optimize the performance and operation of the sensor layer pixel region 107 and circuit layer pixel region 211 without the constraint of having identical row select voltage signals and timing.

Referring now to FIG. 3, there is shown a schematic diagram of a shared architecture of pixel regions in an embodiment in accordance with the invention. Two sensor layer pixel regions 300, 302 on sensor wafer 304 include photodetectors (PD) 306, 308 and transfer gates (TG) 310, 312, respectively. A single charge-to-voltage converter 314 and reset transistor 316 are electrically shared by and physically distributed within sensor layer pixel regions 300, 302. Charge-to-voltage converter 314 is implemented as a floating diffusion in the illustrated embodiment.

The drain of reset transistor 316 is connected to a row select (RS) signal line 318 that is used to perform a row select operation of the sensor layer pixel regions 300, 302. As described earlier, techniques for performing a row select operation are well known in the art and will not be described in detail herein.

Sensor wafer 304 is implemented as a BSI semiconductor wafer in an embodiment in accordance with the invention. Other embodiments in accordance with the invention can configure sensor wafer 304 as a FSI semiconductor wafer. Additionally, in other embodiments in accordance with the invention, more than two photodetectors can share a charge-to-voltage converter and a reset transistor. For example, any n-shared arrangement, such as a four-shared arrangement, can be utilized.

Circuit layer pixel region 320 on circuit wafer 322 includes a source follower input transistor (SF) 324. Source follower input transistor 324 is shared by sensor layer pixel regions 300, 302. The drain of source follower input transistor 324 is connected to a row select (RS) signal line 326. RS signal line is used to perform row select operation of circuit layer pixel region 320. The source of source follower input transistor 324 is connected to column output line 328.

Since source follower input transistor 324 is formed on a separate semiconductor wafer than reset transistor 316, the type and structure of the source follower input transistor can be chosen to independently optimize the performance of the source follower input transistor. Because the only active electrical component in circuit layer pixel region 320 is the source follower input transistor 324, the size of source follower input transistor 324 can be as large, or nearly as large, as the area or size of circuit layer pixel region 320. The size of source follower input transistor 324 can fill or substantially fill circuit layer pixel region 320 in an embodiment in accordance with the invention. The width (W) and length (L) of a source follower input transistor can be made large, where W×L>1 um², even though the size of sensor layer pixel regions 300, 302 on sensor wafer 304 are smaller. For example, if a four-shared architecture is employed on the sensor wafer and the size of the pixel regions on the sensor wafer is 1 um², then the effective size of the pixel region on the circuit wafer is 4 um², and the W×L of the source follower input transistor can be much greater than 1 um². As another example, if a four-shared architecture is employed on the sensor wafer and the size of the pixel regions on the sensor wafer is 0.25 um², then the effective size of the pixel region on the circuit wafer is 1 um², and the W×L of the source follower input transistor can be close to 1 um². Those skilled in the art will appreciate a source follower input transistor having this size provides a low RTS noise readout.

A pixel region interconnect node 330 connects the shared floating diffusion 314 to a gate of a corresponding shared source follower input transistor 324 on the circuit wafer.

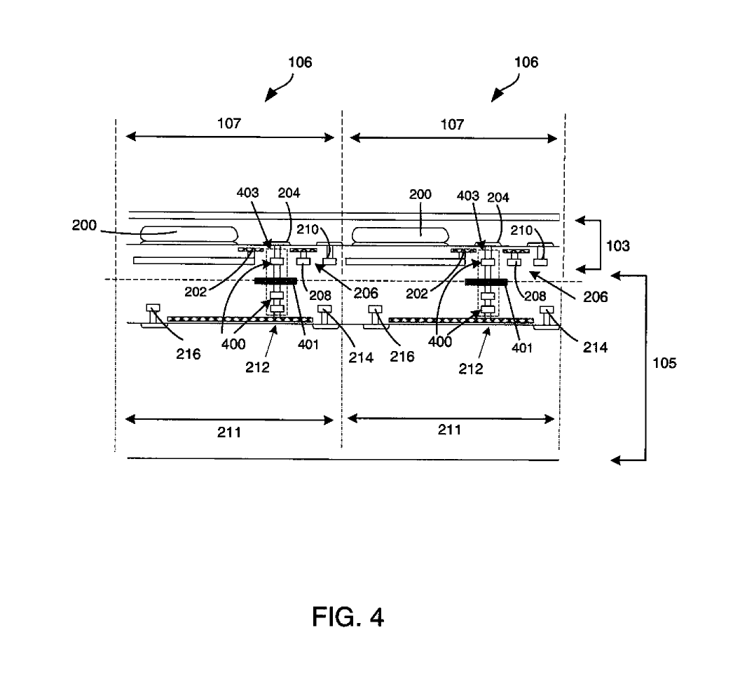

FIG. 4 is a cross-sectional view along line A-A′ in FIG. 1e of two pixel regions 106 having the pixel schematic as shown in FIG. 2 in an embodiment in accordance with the invention. Pixel array 100 includes sensor layer 103 and circuit layer 105. Sensor layer pixel region 107 includes photodetector 200, transfer gate 202, charge-to-voltage converter 204, reset transistor 206, and the gate 208 of reset transistor 206. The drain of reset transistor 206 is connected to row select signal line 210.

Circuit layer pixel region 211 on circuit layer 105 includes source follower input transistor 212. The drain of source follower input transistor 212 is connected to row select signal line 214 that is used to perform row select operation of pixel region 211. Together wafer metallization 400 and contact 401 form a connector 403 that connects charge-to-voltage converter 204 on sensor layer 103 to a gate 220 of source follower input transistor 212 on circuit layer 105. Contact 401 corresponds to node 218 in FIG. 2 and node 330 in FIG. 3. The connector 403 is used to transfer a signal from the charge-to-voltage converter 204 to the source follower input transistor 212. Connector 403 is formed in an interconnect layer. Row select signal line 214 and output 216 are formed in a CMOS device layer (not identified in FIG. 4) in an embodiment in accordance with the invention.

Other embodiments in accordance with the invention can configure the components in sensor layer pixel region 107 on two or more semiconductor wafers instead of one. United States Patent Application Publication 2010/0026895 discloses one such multi-wafer implementation.

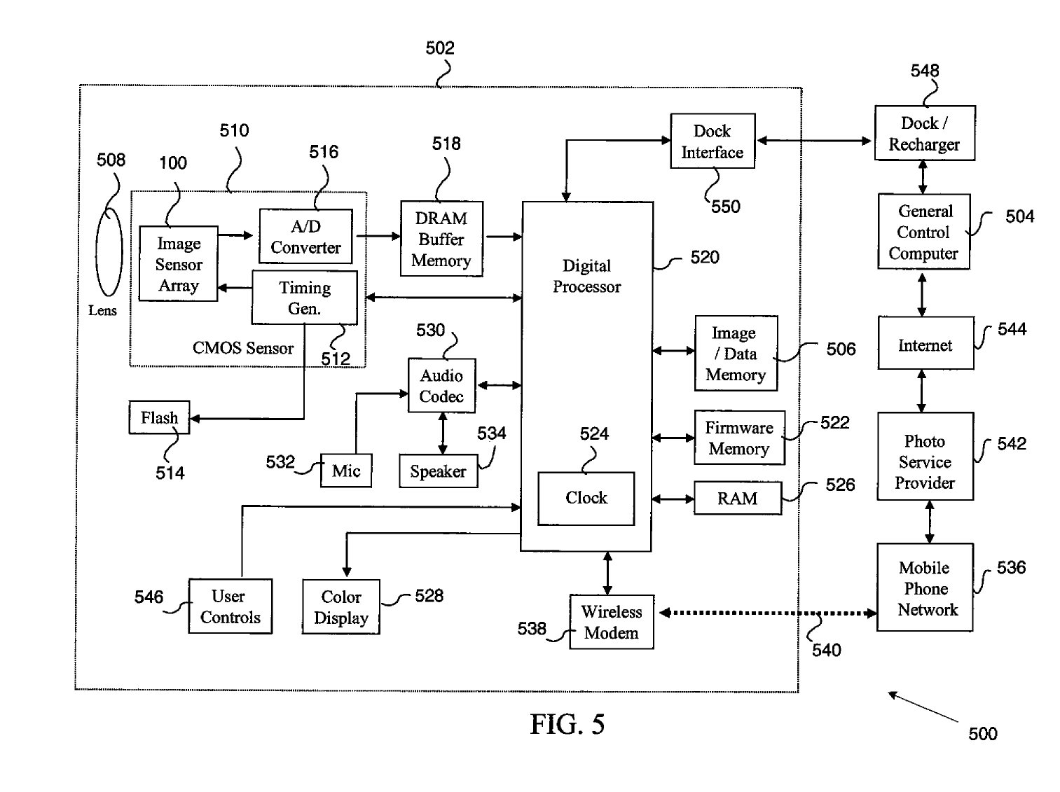

Referring now to FIG. 5, there is shown a block diagram of an imaging system suitable for employing an image sensor as depicted in FIG. 1 in an embodiment in accordance with the invention. Imaging system 500 includes digital camera phone 502 and computing device 504. Digital camera phone 504 is one example of an image capture device that can that can employ an image sensor having two or more semiconductor wafers. Other types of image capture devices that can be used with the present invention include digital still cameras, digital video camcorders, and scanners.

Digital camera phone 502 is a portable, handheld, battery-operated device in an embodiment in accordance with the invention. Digital camera phone 502 produces digital images that are stored in memory 506, which can be, for example, an internal Flash EPROM memory or a removable memory card. Other types of digital image storage media, such as magnetic hard drives, magnetic tape, or optical disks, can alternatively be used to implement memory 506.

Digital camera phone 502 uses lens 508 to focus light from a scene (not shown) onto image sensor pixel array 100 of active pixel sensor 510. Image sensor pixel array 100 provides color image information using the Bayer color filter pattern in an embodiment in accordance with the invention. Image sensor pixel array 100 is controlled by timing generator 512, which also controls flash 514 in order to illuminate the scene when the ambient illumination is low. The analog output signals output from the image sensor pixel array 100 are amplified and converted to digital data by analog-to-digital (VD) converter circuit 516. The digital data are stored in buffer memory 518 and subsequently processed by digital processor 520. Digital processor 520 is controlled by the firmware stored in firmware memory 522, which can be flash EPROM memory. Digital processor 520 includes real-time clock 524, which keeps the date and time even when digital camera phone 502 and digital processor 520 are in a low power state. The processed digital image files are stored in memory 506. Memory 506 can also store other types of data, such as, for example, music files (e.g. MP3 files), ring tones, phone numbers, calendars, and to-do lists.

In one embodiment in accordance with the invention, digital camera phone 502 captures still images. Digital processor 520 performs color interpolation followed by color and tone correction, in order to produce rendered sRGB image data. The rendered sRGB image data are then compressed and stored as an image file in memory 506. By way of example only, the image data can be compressed pursuant to the JPEG format, which uses the known “Exif” image format. This format includes an Exif application segment that stores particular image metadata using various TIFF tags. Separate TIFF tags can be used, for example, to store the date and time the picture was captured, the lens f/number and other camera settings, and to store image captions.

Digital processor 520 produces different image sizes that are selected by the user in an embodiment in accordance with the invention. One such size is the low-resolution “thumbnail” size image. Generating thumbnail-size images is described in commonly assigned U.S. Pat. No. 5,164,831, entitled “Electronic Still Camera Providing Multi-Format Storage Of Full And Reduced Resolution Images” to Kuchta, et al. The thumbnail image is stored in RAM memory 526 and supplied to display 528, which can be, for example, an active matrix LCD or organic light emitting diode (OLED). Generating thumbnail size images allows the captured images to be reviewed quickly on display 528.

In another embodiment in accordance with the invention, digital camera phone 502 also produces and stores video clips. A video clip is produced by summing multiple pixels of image sensor pixel array 100 together (e.g. summing pixels of the same color within each 4 column×4 row area of the image sensor pixel array 100) to create a lower resolution video image frame. The video image frames are read from image sensor pixel array 100 at regular intervals, for example, using a 15 frame per second readout rate.

Audio codec 530 is connected to digital processor 520 and receives an audio signal from microphone (Mic) 532. Audio codec 530 also provides an audio signal to speaker 534. These components are used both for telephone conversations and to record and playback an audio track, along with a video sequence or still image.

Speaker 534 is also used to inform the user of an incoming phone call in an embodiment in accordance with the invention. This can be done using a standard ring tone stored in firmware memory 522, or by using a custom ring-tone downloaded from mobile phone network 536 and stored in memory 506. In addition, a vibration device (not shown) can be used to provide a silent (e.g. non-audible) notification of an incoming phone call.

Digital processor 520 is connected to wireless modem 538, which enables digital camera phone 502 to transmit and receive information via radio frequency (RF) channel 540. Wireless modem 538 communicates with mobile phone network 536 using another RF link (not shown), such as a 3GSM network. Mobile phone network 536 communicates with photo service provider 542, which stores digital images uploaded from digital camera phone 502. Other devices, including computing device 504, access these images via the Internet 544. Mobile phone network 536 also connects to a standard telephone network (not shown) in order to provide normal telephone service in an embodiment in accordance with the invention.

A graphical user interface (not shown) is displayed on display 528 and controlled by user controls 546. User controls 546 include dedicated push buttons (e.g. a telephone keypad) to dial a phone number, a control to set the mode (e.g.

“phone” mode, “calendar” mode” “camera” mode), a joystick controller that includes 4-way control (up, down, left, right) and a push-button center “OK” or “select” switch, in embodiments in accordance with the invention.

Dock 548 recharges the batteries (not shown) in digital camera phone 502. Dock 548 connects digital camera phone 502 to computing device 504 via dock interface 550. Dock interface 550 is implemented as wired interface, such as a USB interface, in an embodiment in accordance with the invention. Alternatively, in other embodiments in accordance with the invention, dock interface 550 is implemented as a wireless interface, such as a Bluetooth or an IEEE 802.11b wireless interface. Dock interface 550 is used to download images from memory 506 to computing device 504. Dock interface 550 is also used to transfer calendar information from computing device 504 to memory 506 in digital camera phone 502.

The invention has been described in detail with particular reference to certain preferred embodiments thereof, but it will be understood that variations and modifications can be effected within the spirit and scope of the invention.

Even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

98 sensor die
99 circuit die
100 pixel array
101 image sensor
102 sensor wafer
104 circuit wafer
106 pixel region
107 sensor layer pixel region
200 photodetector
202 transfer gate
204 charge-to-voltage converter
206 reset transistor
208 gate of reset transistor
210 row select signal line
211 circuit layer pixel region
212 source follower input transistor
214 row select signal line
216 output
218 pixel region interconnect node
300 sensor layer pixel region
302 sensor layer pixel region
304 sensor wafer
306 photodetector
308 photodetector
310 transfer gate
312 transfer gate
314 charge-to-voltage converter
316 reset transistor
318 row select signal line
320 circuit layer pixel region
322 circuit wafer
324 source follower input transistor
326 row select signal line
328 output
330 pixel region interconnect node
400 wafer metallization
401 contact
403 connector
500 imaging system
502 camera phone
504 computing device
506 memory
508 lens
100 image sensor pixel array
510 active pixel sensor
512 timing generator
514 flash
516 analog-to-digital converter
518 buffer memory
520 digital processor
522 firmware memory
524 clock
526 RAM memory
528 display
530 audio codec
532 microphone
534 speaker
536 mobile phone network
538 wireless modem
540 RF channel
542 photo service provider
544 internet
546 user controls
548 dock
550 dock interface

1. An image sensor comprising:
(a) a sensor layer comprising:
a first plurality of pixel regions with at least one pixel region including:
a photodetector for collecting charge in response to incident light;
a charge-to-voltage converter; and
a transfer gate for enabling charge transfer from the photodetector to the charge-to-voltage converter;
(b) a circuit layer connected to the sensor layer and including a second plurality of pixel regions with at least one pixel region consisting of a source follower input transistor associated with one or more pixel regions in the first plurality of pixel regions; and
(c) a connector connecting the charge-to-voltage converter on the sensor layer to a gate of the source follower input transistor in the pixel region on the circuit layer, wherein the connector transfers a signal from the charge-to-voltage converter to the source follower input transistor.

2. The image sensor as in claim 1, wherein the charge-to-voltage converter comprises a floating diffusion.

3. The image sensor as in claim 1, wherein the at least one pixel region on the sensor layer further includes a reset transistor for discharging charge from the charge-to-voltage converter.

4. The image sensor as in claim 3, wherein the reset transistor is shared by two or more pixel regions on the sensor layer.

5. The image sensor as in claim 1, wherein the charge-to-voltage converter is shared by two or more pixel regions on the sensor layer.

6. The image sensor as in claim 1, wherein the at least one pixel region on the circuit layer is connected to a single respective pixel region on the sensor layer, and wherein a size of the source follower input transistor substantially fills an area of the pixel region on the circuit layer.

7. The image sensor as in claim 1, wherein the at least one pixel region on the circuit layer is shared by two or more pixel regions on the sensor layer, and wherein a size of the source follower input transistor substantially fills an area of the pixel region on the circuit layer.

8. An image sensor comprising:
(a) a sensor layer comprising:
a first plurality of pixel regions with at least one pixel region including:
a photodetector for collecting charge in response to incident light;
a charge-to-voltage converter; and
a transfer gate for enabling charge transfer from the photodetector to the charge-to-voltage converter;
(b) a circuit layer connected to the sensor layer and including a second plurality of pixel regions with at least one pixel region consisting of a source follower input transistor associated with one or more pixel regions in the first plurality of pixel regions, wherein a size of the source follower input transistor substantially fills an area of the pixel region on the circuit layer; and
(c) a connector connecting the charge-to-voltage converter on the sensor layer to a gate of the source follower input transistor in the pixel region on the circuit layer, wherein the connector transfers a signal from the charge-to-voltage converter to the source follower input transistor.

9. The image sensor as in claim 8, wherein the at least one pixel region on the sensor layer further includes a reset transistor for discharging charge from the charge-to-voltage converter.

10. The image sensor as in claim 9, wherein the reset transistor is shared by two or more pixel regions on the sensor layer.

11. The image sensor as in claim 8, wherein the charge-to-voltage converter is shared by two or more pixel regions on the sensor layer.

12. The image sensor as in claim 8, wherein the at least one pixel region on the circuit layer is connected to a single respective pixel region on the sensor layer.

13. The image sensor as in claim 8, wherein the at least one pixel region on the circuit layer is shared by two or more pixel regions on the sensor layer.

14. An image capture device comprising:
an image sensor including:
(a) a sensor layer comprising:
a first plurality of pixel regions with at least one pixel region including:
a photodetector for collecting charge in response to incident light;
a charge-to-voltage converter; and
a transfer gate for enabling charge to transfer from the photodetector to the charge-to-voltage converter;
(b) a circuit layer connected to the sensor layer and including a second plurality of pixel regions with at least one pixel region consisting of a source follower input transistor associated with one or more pixel regions in the first plurality of pixel region, wherein a size of the source follower input transistor substantially fills an area of the pixel region on the circuit layer; and
(c) a connector connecting the charge-to-voltage converter on the sensor layer to a gate of the source follower input transistor in a respective pixel region on the circuit layer, wherein the connector transfers a signal from the charge-to-voltage converter to the source follower input transistor.

15. The image capture device of claim 14, wherein the at least one pixel region on the sensor layer further includes a reset transistor for discharging charge from the charge-to-voltage converter.

16. The image capture device as in claim 15, wherein the reset transistor is shared by two or more pixel regions on the sensor layer.

17. The image capture device as in claim 14, wherein the charge-to-voltage converter is shared by two or more pixel regions on the sensor layer.

18. The image capture device as in claim 14, wherein the at least one pixel region on the circuit layer is connected to a single respective pixel region on the sensor layer.

19. The image capture device as in claim 14, wherein the at least one pixel region on the circuit layer is shared by two or more pixel regions on the sensor layer.

20. The image capture device as in claim 14, further comprising a first row select line on the sensor layer and a second row select line on the circuit layer, wherein one or more signals applied to the first row select line have different voltage levels than signals applied to the second row select lines.

21. An image sensor comprising:
(a) a sensor layer comprising:
a first plurality of pixel regions with at least one pixel region including:
a photodetector for collecting charge in response to incident light;
a charge-to-voltage converter;
a transfer gate for enabling charge transfer from the photodetector to the charge-to-voltage converter; and
a first row select line; and
(b) a circuit layer connected to the sensor layer and including a second plurality of pixel regions with at least one pixel region including a distinct second row select line.
